(19) United States
(12) Patent Application Publication
(10) Pub. No.: US 2025/0204160 A1
(43) Pub. Date: Jun. 19, 2025

(54) DISPLAY DEVICE

(71) Applicant: Samsung Display Co., LTD., Yongin-si (KR)

(72) Inventors: Hyun Eok SHIN, Yongin-si (KR); Joon Yong PARK, Yongin-si (KR); Su Kyoung YANG, Yongin-si (KR); Dong Min LEE, Yongin-si (KR)

(21) Appl. No.: 18/776,591

(22) Filed: Jul. 18, 2024

(30) Foreign Application Priority Data
Dec. 14, 2023 (KR) 10-2023-0182183

(51) Int. Cl. H10K 59/122

(52) U.S. Cl. CPC H10K 59/122

(57) ABSTRACT

A display device includes a first pixel electrode disposed on a substrate; a pixel defining layer disposed on the substrate and provided with an opening exposing the first pixel electrode; a first light emitting layer disposed on the first pixel electrode; a first common electrode disposed on the first light emitting layer and including a first layer; a first bank disposed on the pixel defining layer; and a second bank disposed on the first bank, where a side surface of the second bank is protruding more than a corresponding side surface of the first bank, and the first layer includes a first element of silver (Ag) and a second element of group XV element.

This application claims priority to Korean Patent Application No. 10-2023-0182183, filed on Dec. 14, 2023, and all the benefits accruing therefrom under 35 U.S.C. § 119, the content of which in its entirety is herein incorporated by reference.

### BACKGROUND

### 1. Field

Embodiments of the disclosure relate to a display device.

### 2. Description of the Related Art

With the advancement of the information age, the demand for a display device for displaying an image has increased with various forms. For example, the display device has been applied to various electronic devices such as a smart phone, a digital camera, a laptop computer, a navigator and a smart television. The display device may be a flat panel display device such as a liquid crystal display device, a field emission display device or an organic light emitting display device. Among such flat panel display devices, the light emitting display device includes a light emitting element in which each of pixels of a display panel may self-emit light, thereby displaying an image even without a backlight unit that provides the display panel with light.

Recently, the display device has been applied to a glasses-type device to provide virtual reality and augmented reality. In order to be applied to the glasses-type device, the display device is implemented at a very small size of 2 inches or less, and it is desired for the display device to have high pixel integration so that the display device may be implemented at high resolution. For example, the display device may have high pixel integration of 400 pixels per inch (PPI) or more.

### SUMMARY

As described above, a display device applied to a glasses-type device is implemented at a very small size, but an area of a light emission area thereof in which a light emitting element is disposed is reduced when the display device has high pixel integration. Therefore, it may be difficult to implement light emitting elements separated for each light emission area by a mask process.

An embodiment of the disclosure is to provide a display device that may form light emitting elements separated for each light emission area without a mask process.

Another embodiment of the disclosure is to provide a display device in which contact resistance of a common electrode of a light emitting element is low.

The embodiments of the disclosure are not limited to those mentioned above and additional objects of the disclosure, which are not mentioned herein, will be clearly understood by those skilled in the art from the following description of the disclosure.

According to an embodiment of the disclosure, a display device includes a first pixel electrode disposed on a substrate; a pixel defining layer disposed on the substrate and provided with an opening exposing the first pixel electrode; a first light emitting layer disposed on the first pixel electrode; a first common electrode disposed on the first light emitting layer and including a first layer; a first bank disposed on the pixel defining layer; and a second bank disposed on the first bank, where a side surface of the second bank is protruding more than a corresponding side surface of the first bank, and the first layer includes a first element of silver (Ag) and a second element of group XV element.

In an embodiment, a ratio of the second element to a total number of atoms included in the first layer may be in a range of about 0.2 atomic percent (at %) to about 5.0 at %.

In an embodiment, the second element may be one or two selected from bismuth (Bi) and antimony (Sb).

In an embodiment, the first layer may further include a third element including at least one selected from copper (Cu), zinc (Zn), indium (In), and tin (Sn).

In an embodiment, a sum of ratios of the second and third elements to the total number of atoms included in the first layer may be about 0.5 at % or greater.

In an embodiment, a ratio of the second element to the total number of atoms included in the first layer may be greater than a ratio of the third element to the total number of atoms included in the first layer.

In an embodiment, the first common electrode may further include a second layer including at least one selected from pure silver (pure Ag) and an AgMg alloy.

In an embodiment, the first layer may be disposed on the first light emitting layer, and the second layer may be disposed on the first layer.

In an embodiment, the second layer may be disposed on the first light emitting layer, and the first layer may be disposed on the second layer.

In an embodiment, a thickness of the first common electrode may be in a range of about 90 angstroms (Å) to about 150 Å.

In an embodiment, a thickness of the first layer may be 0.8 to 1.2 times a thickness of the second layer.

In an embodiment, the display device may further include an auxiliary electrode disposed on the common electrode.

In an embodiment, the auxiliary electrode may include a transparent conductive oxide (TCO).

In an embodiment, the display device may further include a residual pattern disposed between an upper surface of the first pixel electrode and a lower surface of the pixel defining layer.

According to an embodiment of the disclosure, a display device includes a first pixel electrode disposed on a substrate; a pixel defining layer disposed on the substrate and provided with an opening exposing the first pixel electrode; a first light emitting layer disposed on the first pixel electrode; a first common electrode disposed on the first light emitting layer and including a first element of silver (Ag) and a second element of group XV element; a first bank disposed on the pixel defining layer; a second bank disposed on the first bank, where a side surface of the second bank is protruding more than a corresponding side surface of the first bank; a first inorganic layer disposed on the first common electrode and the second bank; and an organic encapsulation layer disposed between the second bank and the first inorganic layer.

In an embodiment, the first common electrode may include a first layer containing the first element of silver (Ag) and the second element of group XV element; and a second layer including at least one selected from pure silver (pure Ag) and an AgMg alloy.

In an embodiment, the first inorganic layer may be in contact with a lower surface of the second bank.

In an embodiment, the organic encapsulation layer may be in contact with the side surface of the second bank.

According to an embodiment of the disclosure, a display device includes a first pixel electrode disposed on a substrate; a pixel defining layer disposed on the substrate and provided with an opening exposing the first pixel electrode; a first light emitting layer disposed on the first pixel electrode; a first common electrode disposed on the first light emitting layer and including a first layer; a first bank disposed on the pixel defining layer; and a second bank disposed on the first bank, where a side surface of the second bank is protruding more than a corresponding side surface of the first bank, the first layer includes a first element of silver (Ag), one or two second elements selected from bismuth (Bi) and antimony (Sb), and a third element including at least one selected from copper (Cu), zinc (Zn), indium (In), and tin (Sn), and a ratio of the first element to a total number of atoms included in the first layer is about 95.0 at % or greater.

In an embodiment, a thickness of the first common electrode may be in a range of about 90 Å to about 150 Å.

In the display device according to embodiments, a common electrode of thin thickness and low resistance may be provided and viewing angle characteristics or/and light emission characteristics may be improved.

The effects according to embodiments of the disclosure are not limited to those mentioned above and more various effects are included in the following description of the disclosure.

### BRIEF DESCRIPTION OF THE DRAWINGS

The above and other features of embodiments of the disclosure will become more apparent by describing in detail embodiments thereof with reference to the attached drawings, in which:

FIG. 1 is a perspective view illustrating a display device according to an embodiment;

FIG. 2 is a cross-sectional view illustrating the display device of FIG. 1 viewed from a side;

FIG. 3 is a plan view illustrating an arrangement of light emission area in a display area of a display device according to an embodiment;

FIG. 4 is a cross-sectional view illustrating a portion of a display device according to an embodiment;

FIG. 5 is an enlarged view illustrating area A1 of FIG. 4;

FIG. 6 is a cross-sectional view illustrating an agglomeration phenomenon of a common electrode;

FIG. 7 shows an agglomeration phenomenon of Comparative example 1 observed using a scanning electron microscope (SEM);

FIG. 8 shows an agglomeration of Comparative example 2 observed using an atomic force microscope (AFM);

FIG. 9 shows a surface of Example 1 observed using an AFM; and

FIGS. 10 to 12 are cross-sectional views of a portion of a display device according to various embodiments.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. In contrast, when an element is referred to as being “directly on” another element, there are no intervening elements present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described with reference to the accompanying drawings.

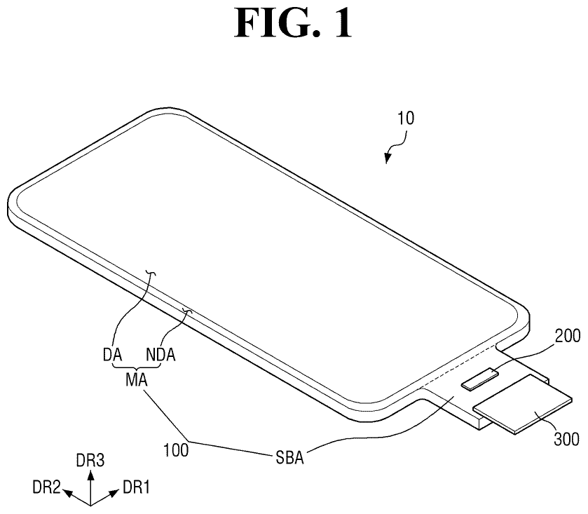

FIG. 1 is a perspective view illustrating a display device according to an embodiment.

Referring to FIG. 1, a display device 10 according to an embodiment may be included in an electronic device to provide a screen displayed in the electronic device. The electronic device may refer to all electronic devices that provide a display screen. For example, a television, a laptop computer, a monitor, an advertising board, Internet of Things, a mobile phone, a smart phone, a tablet personal computer (PC), an electronic watch, smart glasses, a smart watch, a watch phone, a head mounted display, a mobile communication terminal, an electronic diary, an electronic book, a portable multimedia player (PMP), a navigator, a game machine, a digital camera, a camcorder or the like, which provide a display screen, may be included in the electronic device.

Various modifications may be made in a shape of the display device 10. In an embodiment, for example, the display device 10 may have a shape similar to a rectangular shape having a short side in a first direction DR1 and a long side in a second direction DR2. A corner where the short side in the first direction DR1 and the long side in the second direction DR2 meets may be rounded to have a curvature, but is not limited thereto and may formed at a right angle. A planar shape of the display device 10 may be formed to be similar to other polygonal shapes, a circular shape or an oval shape without being limited to the rectangular shape.

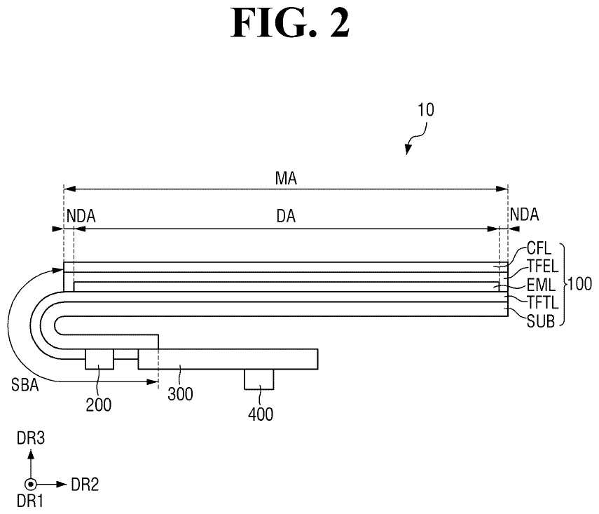

In an embodiment, the display device 10 may include a display panel 100, a display driver 200, a circuit board 300, and a touch driver 400 (shown in FIG. 2).

The display panel 100 may include a main area MA and a sub-area SBA.

The main area MA may include a display area DA including pixels for displaying an image, and a non-display area NDA disposed near the display area DA. The display area DA may emit light from a plurality of light emission areas or a plurality of opening areas. In an embodiment, for example, the display panel 100 may include a pixel circuit including switching elements, a pixel defining layer defining a light emission area or an opening area, and a self-light emitting element.

In an embodiment, for example, the self-light emitting element may include at least one of an organic light emitting diode (LED) including an organic light emitting layer, a quantum dot LED including a quantum dot light emitting layer, an inorganic LED including an inorganic semiconductor or a micro LED, but the disclosure is not limited thereto.

A plurality of pixels, a plurality of scan lines, a plurality of data lines and a plurality of power lines may be disposed in the display area DA. Each of the plurality of pixels may be defined as a minimum unit for emitting light, and each of the above-described self-light emitting elements may be each pixel. The plurality of scan lines may supply a scan signal received from the scan driver to the plurality of pixels. The plurality of data lines may supply a data voltage received from the display driver 200 to the plurality of pixels. The plurality of power lines may supply a power voltage received from the display driver 200 to the plurality of pixels.

The non-display area NDA may be an outer area of the display area DA. The non-display area NDA may be defined as an edge area of the main area MA of the display panel 100. The non-display area NDA may include a scan driver for supplying scan signals to scan lines and fan-out lines for connecting the display driver 200 with the display area DA.

The sub-area SBA may extend from one side of the main area MA. The sub-area SBA may include a flexible material capable of being subjected to bending, folding, rolling and the like. In an embodiment, for example, in a state where the sub-area SBA is bent, the sub-area SBA may overlap the main area MA in a thickness direction (third direction DR3). The sub-area SBA may include a display driver 200 and a pad portion connected to the circuit board 300. In another embodiment, the sub-area SBA may be omitted, and the display driver 200 and the pad portion may be disposed in the non-display area NDA.

The display driver 200 may output signals and voltages for driving the display panel 100. The display driver 200 may supply data voltages to the data lines. The display driver 200 may supply the power voltage to the power line, and supply scan control signals to the scan driver. The display driver 200 may be formed of an integrated circuit (IC), and may be packaged on the display panel 100 by a chip on glass (COG) mode, a chip on plastic (COP) mode or an ultrasonic bonding mode. In an embodiment, for example, the display driver 200 may be disposed in the sub-area SBA, and may overlap the main area MA in the thickness direction (third direction DR3) by bending of the sub-area SBA. In another embodiment, for example, the display driver 200 may be packaged on the circuit board 300.

The circuit board 300 may be attached onto the pad portion of the display panel 100 using an anisotropic conductive film (ACF). Lead lines of the circuit board 300 may electrically be connected to the pad portion of the display panel 100. The circuit board 300 may be a flexible printed circuit board, a printed circuit board or a flexible film such as a chip on film.

FIG. 2 is a cross-sectional view illustrating the display device of FIG. 1 viewed from a side. In detail, FIG. 2 relates to a side of the display device of FIG. 1, which is in a folded state.

Referring to FIG. 2, in an embodiment, the display panel 100 may include a substrate SUB, a thin film transistor layer TFTL, a light emitting element layer EML, a thin film encapsulation layer TFEL, and a color filter layer CFL.

The substrate SUB may be a base substrate or a base member. The substrate SUB may be a flexible substrate capable of being subjected to bending, folding, rolling or the like. In an embodiment, for example, the substrate SUB may include a polymer resin such as polyimide (PI), but is not limited thereto. In another embodiment, the substrate SUB may include a glass material or a metal material.

The thin film transistor layer TFTL may be disposed on the substrate SUB. The thin film transistor layer TFTL may include a plurality of thin film transistors constituting a pixel circuit of pixels. The thin film transistor layer TFTL may further include scan lines, data lines, power lines, scan control lines, fan-out lines for connecting the display driver 200 with the data lines, and lead lines for connecting the display driver 200 with the pad portion. Each of the thin film transistors may include a semiconductor area, a source electrode, a drain electrode and a gate electrode. In an embodiment, for example, when the scan driver is formed at one side of the non-display area NDA of the display panel 100, the scan driver may include thin film transistors.

The thin film transistor layer TFTL may be disposed in the display area DA, the non-display area NDA and the sub-area SBA. The thin film transistors, the scan lines, the data lines and the power lines of respective pixels of the thin film transistor layer TFTL may be disposed in the display area DA. The scan control lines and the fan-out lines of the thin film transistor layer TFTL may be disposed in the non-display area NDA. The lead lines of the thin film transistor layer TFTL may be disposed in the sub-area SBA.

The light emitting element layer EML may be disposed on the thin film transistor layer TFTL. The light emitting element layer EML may include a plurality of light emitting elements that include a first electrode, a second electrode and a light emitting layer to emit light, and a pixel defining layer that defines pixels. The plurality of light emitting elements of the light emitting element layer EML may be disposed in the display area DA.

In an embodiment, the light emitting layer may be an organic light emitting layer that includes an organic material. The light emitting layer may include a hole transporting layer, an organic light emitting layer and an electron transporting layer. When the first electrode receives a voltage through the thin film transistor of the thin film transistor layer TFTL and the second electrode receives a cathode voltage, holes and electrons may move to the organic light emitting layer through the hole transporting layer and the electron transporting layer, respectively and may be combined with each other in the organic light emitting layer to emit light.

In another embodiment, the light emitting element may include a quantum dot LED including a quantum dot light emitting layer, an inorganic LED including an inorganic semiconductor, or a micro LED.

The thin film encapsulation layer TFEL may cover an upper surface and sides of the light emitting element layer EML and protect the light emitting element layer EML. The thin film encapsulation layer TFEL may include at least one inorganic film and at least one organic film to encapsulate the light emitting element layer EML.

The color filter layer CFL may be disposed on the thin film encapsulation layer TFEL. The color filter layer CFL may include a plurality of color filters respectively corresponding to the plurality of light emission areas. Each of the color filters may selectively transmit light of a particular wavelength and block or absorb light of another wavelength. The color filter layer CFL may absorb a portion of light introduced from the outside of the display device 10 to reduce reflective light due to external light. Therefore, the color filter layer CFL may prevent distortion of a color, which is caused by external light reflection, from occurring.

In an embodiment, the color filter layer CFL is directly disposed on the thin film encapsulation layer TFEL, such that the display device 10 may not include a separate substrate for the color filter layer CFL. Therefore, a thickness of the display device 10 may be relatively reduced.

In some embodiments, the display device 10 may further include an optical device. The optical device may emit or receive light of an infrared, ultraviolet or visible band. In an embodiment, for example, the optical device may be an optical sensor for sensing light incident on the display device 10, such as a proximity sensor, an illuminance sensor, a camera sensor, a fingerprint sensor or an image sensor.

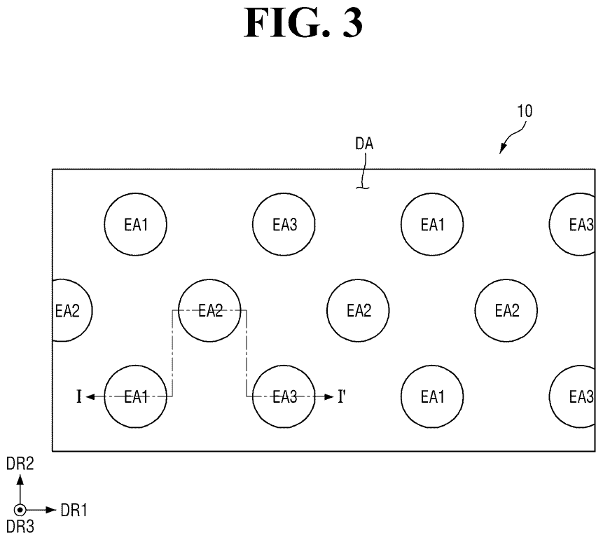

FIG. 3 is a plan view illustrating a portion of a display device according to an embodiment. FIG. 3 is a plan view illustrating arrangement of light emission areas EA1, EA2, and EA3 in a display area DA of a display device 10.

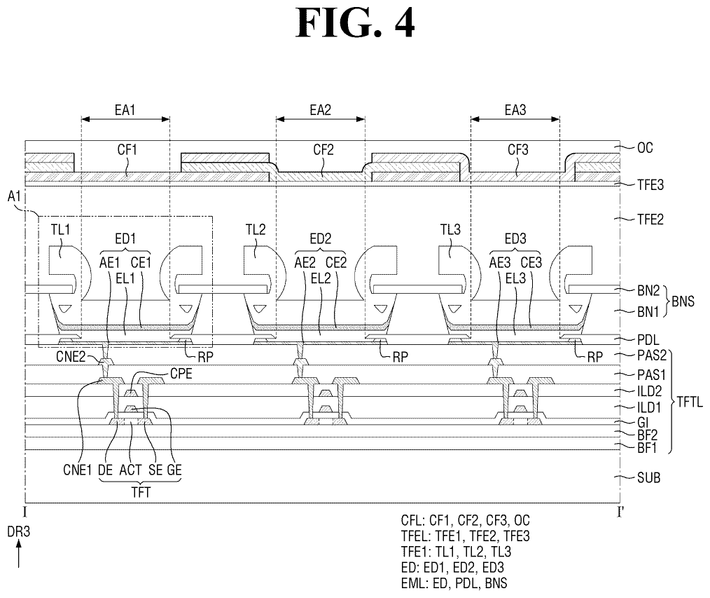

Referring to FIG. 3, an embodiment of the display device 10 may include a plurality of light emission areas EA1, EA2, and EA3 disposed in the display area DA. The light emission areas EA1, EA2, and EA3 may include a first light emission area EA1, a second light emission area EA2, and a third light emission area EA3 that emit light of different colors, respectively. In an embodiment, the first to third light emission areas EA1, EA2, and EA3 may emit red, green, or blue light, respectively, and the color of light emitted from each of the light emission areas EA1, EA2, and EA3 may be different depending on the types of light emitting elements (′ED1′, ‘ED2’, and ‘ED3’ in FIG. 4) to be described later. In an embodiment, for example, the first light emission area EA1 may emit a first light of red color, the second light emission area EA2 may emit a second light of green color, and the third light emission area EA3 may emit a third light of blue color. However, the disclosure is not limited thereto.

The plurality of light emission areas EA1, EA2, and EA3 may be disposed in a Pentile™ type, for example, a diamond Pentile™ type. In an embodiment, for example, the first light emission area EA1 and the third light emission area EA3 may be disposed to be spaced apart from each other in the first direction DR1, and may be alternately disposed in the first direction DR1 and the second direction DR2. The second light emission area EA2 may be spaced apart from another adjacent second light emission area EA2 in the first direction DR1 and the second direction DR2. The second light emission area EA2 and the first light emission area EA1, or the second light emission area EA2 and the third light emission area EA3 may be alternately arranged along any direction in a plane formed by the first direction DR1 and the second direction DR2.

The first to third light emission areas EA1, EA2, and EA3 may be defined by a pixel defining layer (‘PDL’ in FIG. 4) to be described later.

FIG. 4 is a cross-sectional view illustrating a portion of a display device according to an embodiment. Specifically, FIG. 4 is a cross-sectional view of portion I-I′ of FIG. 3 and illustrates cross-sections of the substrate SUB, the thin film transistor layer TFTL, the light emitting element layer EML, the thin film encapsulation layer TFEL, and the color filter layer CFL.

The thin film transistor layer TFTL may include a first buffer layer BF1, a lower metal layer (not shown), a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic film capable of preventing permeation of air or moisture. In an embodiment, for example, the first buffer layer BF1 may include a plurality of inorganic films alternately stacked.

The lower metal layer (not shown) may be disposed on the first buffer layer BF1. In an embodiment, for example, the lower metal layer may be formed of or defined by a single layer or a multi-layer, each layer therein including or made of at least one selected from molybdenum (Mo), aluminum (Al), chromium (Cr), gold (Au), titanium (Ti), nickel (Ni), neodymium (Nd), and copper (Cu), or an alloy thereof.

The second buffer layer BF2 may cover the first buffer layer BF1 and the lower metal layer. The second buffer layer BF2 may include an inorganic film capable of preventing permeation of air or moisture. In an embodiment, for example, the second buffer layer BF2 may include a plurality of inorganic films alternately stacked.

The thin film transistor TFT may be disposed on the second buffer layer BF2, and may constitute a pixel circuit of each of the plurality of pixels. In an embodiment, for example, the thin film transistor TFT may be a driving transistor or a switching transistor of the pixel circuit. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the lower metal layer and the gate electrode GE in the thickness direction DR3, and may be insulated from the gate electrode GE by the gate insulating layer GI. In a portion of the semiconductor layer ACT, a material of the semiconductor layer ACT may become a conductor to form the source electrode SE and the drain electrode DE.

The gate electrode GE may be disposed on the gate insulating layer GI. The gate electrode GE may overlap the semiconductor layer ACT in the thickness direction DR3, with the gate insulating layer GI interposed therebetween.

The gate insulating layer GI may be disposed on the semiconductor layer ACT. For example, the gate insulating layer GI may cover the semiconductor layer ACT and the second buffer layer BF2, and may insulate the semiconductor layer ACT and the gate electrode GE from each other. The gate insulating layer GI may include a contact hole through which the first connection electrode CNE1 penetrates.

The first interlayer insulating layer ILD1 may cover the gate electrode GE and the gate insulating layer GI. The first interlayer insulating layer ILD1 may be provided with a contact hole through which the first connection electrode CNE1 extends or is disposed. The contact hole of the first interlayer insulating layer ILD1 may be connected to the contact hole of the gate insulating layer GI and a contact hole of the second interlayer insulating layer ILD2.

The capacitor electrode CPE may be disposed on the first interlayer insulating layer ILD1. The capacitor electrode CPE may overlap the gate electrode GE in the thickness direction DR3. The capacitor electrode CPE and the gate electrode GE may form a capacitance.

The second interlayer insulating layer ILD2 may cover the capacitor electrode CPE and the first interlayer insulating layer ILD1. The second interlayer insulating layer ILD2 may be provided with a contact hole through which the first connection electrode CNE1 extends or is disposed. The contact hole of the second interlayer insulating layer ILD2 may be connected to the contact hole of the first interlayer insulating layer ILD1 and the contact hole of the gate insulating layer GI.

The first connection electrode CNE1 may be disposed on the second interlayer insulating layer ILD2. The first connection electrode CNE1 may electrically connect the drain electrode DE of the thin film transistor TFT and the second connection electrode CNE2 to each other. The first connection electrode CNE1 may be inserted into the contact holes defined or formed in the second interlayer insulating layer ILD2, the first interlayer insulating layer ILD1, and the gate insulating layer GI to be in contact with the drain electrode DE of the thin film transistor TFT.

The first passivation layer PAS1 may cover the first connection electrode CNE1 and the second interlayer insulating layer ILD2. The first passivation layer PAS1 may protect the thin film transistor TFT. The first passivation layer PAS1 may include a contact hole through which the second connection electrode CNE2 penetrates.

The second connection electrode CNE2 may be disposed on the first passivation layer PAS1. The second connection electrode CNE2 may electrically connect the first connection electrode CNE1 and pixel electrodes AE1, AE2, and AE3 of a light emitting element ED to each other. The second connection electrode CNE2 may be inserted into the contact hole formed in the first passivation layer PAS1 and be in contact with the first connection electrode CNE1.

The second passivation layer PAS2 may cover the second connection electrode CNE2 and the first passivation layer PAS1. The second passivation layer PAS2 may be provided with contact holes through which the pixel electrodes AE1, AE2, and AE3 of the light emitting element ED extend or are disposed.

The light emitting element layer EML may be disposed on the thin film transistor layer TFTL. The light emitting element layer EML may include a light emitting element ED, a pixel defining layer PDL, and a bank structure BNS. The light emitting element ED may include pixel electrodes AE1, AE2, and AE3, light emitting layers EL1, EL2, and EL3, and common electrodes CE1, CE2, and CE3.

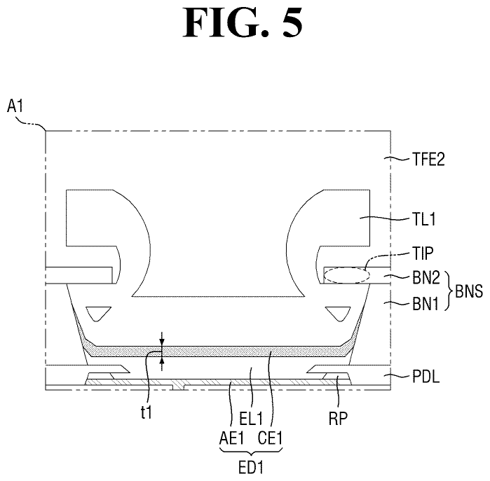

FIG. 5 is an enlarged view illustrating a first light emission area, specifically area A1 of FIG. 4.

Referring to FIG. 5 in addition to FIG. 4, an embodiment of the display device 10 may include a plurality of light emission areas EA1, EA2, and EA3 disposed in the display area DA. The light emission areas EA1, EA2, and EA3 may be defined as areas where the pixel electrodes AE1, AE2, and AE3, the light emitting layers EL1, EL2, and EL3, and the common electrodes CE1, CE2, and CE3 overlap each other in the thickness direction DR3 of the substrate SUB. The light emission areas EA1, EA2, and EA3 may include an area where light is emitted from the light emitting elements ED1, ED2, and ED3 in which the pixel electrodes AE1, AE2, and AE3, the light emitting layers EL1, EL2, and EL3, and the common electrodes CE1, CE2, and CE3 are sequentially stacked and passes through the color filter layer CFL in the third direction DR3. The light emission areas EA1, EA2, and EA3 may include a first light emission area EA1, a second light emission area EA2, and a third light emission area EA3 that are spaced apart from each other and emit light of a same color or different colors.

In an embodiment, areas or sizes of the first to third light emission areas EA1, EA2 and EA3 may be the same as one another. In an embodiment, for example, in the display device 10, the first light emission area EA1, the second light emission area EA2 and the third light emission area EA3 may have a same size (e.g., a planar area) as each other, but are not limited thereto. In an embodiment of the display device 10, the first to third light emission areas EA1, EA2 and EA3 may have different areas or sizes from each other. In an embodiment, for example, the size of the second light emission area EA2 may be larger than that of each of the first light emission area EA1 and the third light emission area EA3, and the size of the third light emission area EA3 may be larger than that of the first light emission area EA1. The intensity of light emitted from the corresponding light emission areas EA1, EA2, and EA3 may be varied depending on the sizes of the light emission areas EA1, EA2, and EA3, and the sizes of the light emission areas EA1, EA2, and EA3 may be adjusted so that a color of a screen displayed on the display device 10 may be controlled. In an embodiment, as shown in FIG. 4, the sizes of the light emission areas EA1, EA2, and EA3 may be the same as one another, but are not limited thereto.

In an embodiment of the display device 10, one first light emission area EA1, one second light emission area EA2 and one third light emission area EA3, which are disposed to be adjacent to one another, may form one pixel group. One pixel group may include the light emission areas EA1, EA2, and EA3 that emit light of different colors, thereby representing a white gray scale, but the disclosure is not limited thereto. A combination of the light emission areas EA1, EA2, and EA3 constituting one pixel group may be variously modified depending on the arrangement of the light emission areas EA1, EA2, and EA3 and the colors of the light emitted from the light emission areas EA1, EA2, and EA3.

The display device 10 may include a plurality of light emitting elements ED1, ED2, and ED3 respectively disposed in different light emission areas EA1, EA2, and EA3. The light emitting elements ED1, ED2, and ED3 may include a first light emitting element ED1 disposed in the first light emission area EA1, a second light emitting element ED2 disposed in the second light emission area EA2, and a third light emitting element ED3 disposed in the third light emission area EA3.

The light emitting elements ED1, ED2, and ED3 may include pixel electrodes AE1, AE2, and AE3, light emitting layers EL1, EL2, and EL3 and common electrodes CE1, CE2, and CE3, and the light emitting elements ED1, ED2, and ED3 respectively disposed in the different light emission areas EA1, EA2, and EA3 may emit light of different colors depending on materials of the light emitting layers EL1, EL2, and EL3. In an embodiment, for example, the first light emitting element ED1 disposed in the first light emission area EA1 may emit first light of a first color, which has a peak wavelength in a range of 610 nanometers (nm) to 650 nm, the second light emitting element ED2 disposed in the second light emission area EA2 may emit second light of a green color, which has a peak wavelength in a range of 510 nm to 550 nm, and the third light emitting element ED3 disposed in the third light emission area EA3 may emit third light of a blue color, which has a peak wavelength in a range of 440 nm to 480 nm. The first to third light emission areas EA1, EA2, and EA3 constituting one pixel may include the light emitting elements ED1, ED2, and ED3 for emitting light of different colors to represent a white gray scale. Alternatively, as the light emitting layers EL1, EL2, and EL3 may include two or more materials for emitting light of different colors, one light emitting layer may emit mixture light. In an embodiment, for example, the light emitting layers EL1, EL2, and EL3 may include a material for emitting red light and a material for emitting green light together to emit yellow light, or may include all of a material for emitting red light, a material for emitting green light and a material for emitting blue light to emit white light.

The pixel electrodes AE1, AE2, and AE3 may be disposed on the second passivation layer PAS2. The pixel electrodes AE1, AE2, and AE3 may be disposed in the plurality of light emission areas EA1, EA2, and EA3, respectively. The pixel electrodes AE1, AE2, and AE3 may include a first pixel electrode AE1 disposed in the first light emission area EA1, a second pixel electrode AE2 disposed in the second light emission area EA2, and a third pixel electrode AE3 disposed in the third light emission area EA3. The first pixel electrode AE1, the second pixel electrode AE2 and the third pixel electrode AE3 may be spaced apart from one another on the second passivation layer PAS2, respectively.

The pixel electrodes AE1, AE2, and AE3 may be electrically connected to the drain electrode DE of the thin film transistor TFT through the first and second connection electrodes CNE1 and CNE2. Edges of the spaced pixel electrodes AE1, AE2, and AE3 may be covered by the pixel defining layer PDL, so that the first to third pixel electrodes AE1, AE2, and AE3 may be insulated from one another.

The pixel electrodes AE1, AE2, and AE3 may include a transparent electrode material and/or a conductive metal material, and may have a single-layered or multi-layered structure. The conductive metal material may include at least one selected from silver (Ag), copper (Cu), aluminum (Al), nickel (Ni), lanthanum (La), titanium (Ti) and titanium nitride (TiN). The transparent electrode material may include at least one selected from indium tin oxide (ITO), indium zinc oxide (IZO) and indium tin zinc oxide (ITZO).

The pixel defining layer PDL may be disposed on the second passivation layer PAS2, a residual pattern RP and the pixel electrodes AE1, AE2, and AE3. The pixel defining layer PDL may be disposed on the second passivation layer PAS2, and may cover sides of the pixel electrodes AE1, AE2, and AE3 and the residual pattern RP with openings to expose a portion of upper surfaces of the pixel electrodes AE1, AE2, and AE3. In an embodiment, for example, the pixel defining layer PDL may define an opening to expose the first pixel electrode AE1 in the first light emission area EA1, and the first light emitting layer EL1 may be disposed directly on the first pixel electrode AE1.

The pixel defining layer PDL may include an inorganic insulating material. The pixel defining layer PDL may include at least one selected from silicon nitride, silicon oxynitride, silicon oxide, titanium oxide, aluminum oxide, tantalum oxide, hafnium oxide, zinc oxide and amorphous silicon, but the disclosure is not limited thereto.

According to an embodiment, the pixel defining layer PDL is disposed on the pixel electrodes AE1, AE2, and AE3, and may be spaced apart from the upper surfaces of the pixel electrodes AE1, AE2, and AE3. The pixel defining layer PDL may not directly contact the upper surfaces of the pixel electrodes AE1, AE2, and AE3 while partially overlapping the upper surfaces of the pixel electrodes AE1, AE2, and AE3 in the thickness direction DR3 of the substrate SUB, and the residual pattern RP may be disposed between the lower surface of the pixel defining layer PDL and the upper surfaces of the pixel electrodes AE1, AE2, and AE3. However, the pixel defining layer PDL may directly contact the sides of the pixel electrodes AE1, AE2, and AE3. Corresponding sides of the pixel defining layer PDL (i.e., sides of the pixel defining layer PDL corresponding to the light emission areas EA1, EA2, and EA3 or sides of the pixel defining layer PDL defining the openings) may be more protruded inwardly toward centers of the light emission areas EA1, EA2, and EA3 than corresponding sides of the second bank BN2 is.

The residual pattern RP may be disposed on the edge of each of the pixel electrodes AE1, AE2, and AE3. The pixel defining layer PDL may not directly contact the upper surfaces of the pixel electrodes AE1, AE2, and AE3 due to the residual pattern RP. The residual pattern RP may include a metal or an oxide semiconductor material. In the drawing, sides of the residual pattern RP, which are directed toward the light emission areas EA1, EA2, and EA3, are only illustrated as being more recessed than the sides of the pixel defining layer PDL, but the disclosure is not limited thereto. The corresponding sides of the residual pattern RP may be more protruded than the corresponding sides of the pixel defining layer PDL toward the centers of the light emission areas EA1, EA2, and EA3, or may be aligned with the corresponding sides of the pixel defining layer PDL. The corresponding sides of the pixel defining layer PDL may be the innermost sides directed toward the light emission areas EA1, EA2, and EA3.

The light emitting layers EL1, EL2, and EL3 may be disposed on the pixel electrodes AE1, AE2, and AE3. The light emitting layers EL1, EL2, and EL3 may be organic light emitting layers including or made of an organic material, and may be formed on the pixel electrodes AE1, AE2, and AE3 through a deposition process. The light emitting layers EL1, EL2, and EL3 may have a multi-layered structure, and each of a hole injection material, a hole transporting material, a light emitting material, an electron transporting material and/or an electron injection material may constitute a layer. When the thin film transistor TFT applies a predetermined voltage to the pixel electrodes AE1, AE2, and AE3 of the light emitting elements ED1, ED2, and ED3 and the common electrodes CE1, CE2, and CE3 of the light emitting elements ED1, ED2, and ED3 receive a common voltage or a cathode voltage, holes and electrons may be injected and transported, and holes and electrons may be combined with each other in the light emitting layers EL1, EL2, and EL3 to emit light.

The light emitting layers EL1, EL2, and EL3 may include a first light emitting layer EL1, a second light emitting layer EL2, and a third light emitting layer EL3, which are disposed in the different light emission areas EA1, EA2, and EA3, respectively. The first light emitting layer EL1 may be disposed on the first pixel electrode AE1 in the first light emission area EA1, the second light emitting layer EL2 may be disposed on the second pixel electrode AE2 in the second light emission area EA2, and the third light emitting layer EL3 may be disposed on the third pixel electrode AE3 in the third light emission area EA3. The plurality of light emitting layers EL1, EL2, and EL3 may emit light of different colors, respectively, or one of the light emitting layers EL1, EL2, and EL3 may emit mixture light. In an embodiment, the first light emitting layer EL1 may emit red light, the second light emitting layer EL2 may emit green light, and the third light emitting layer EL3 may emit blue light. In another embodiment, the first light emitting layer EL1 may emit yellow light, which is mixture light of red light and green light, and the second light emitting layer EL2 may emit blue light. In still another embodiment, the first light emitting layer EL1 may emit white light, which is mixture light of red light, green light and blue light.

The light emitting layers EL1, EL2, and EL3 may be disposed on an upper surface of the pixel defining layer PDL. In an embodiment, a portion of the light emitting layers EL1, EL2, and EL3 may be disposed in spaces between the pixel electrodes AE1, AE2, and AE3 and the pixel defining layer PDL. In an embodiment, the light emitting layers EL1, EL2, and EL3 may be in contact with the pixel defining layer PDL, the residual pattern RP and the pixel electrodes AE1, AE2, and AE3.

The common electrodes CE1, CE2, and CE3 may be disposed on the light emitting layers EL1, EL2, and EL3. The common electrodes CE1, CE2, and CE3 may include a transparent conductive material so that light generated from the light emitting layers EL1, EL2, and EL3 may be emitted. The common electrodes CE1, CE2, and CE3 may receive a common voltage or a low potential voltage. When the pixel electrodes AE1, AE2, and AE3 receive a voltage corresponding to the data voltage and the common electrodes CE1, CE2, and CE3 receive a low potential voltage, a potential difference may be formed between the pixel electrodes AE1, AE2, and AE3 and the common electrodes CE1, CE2, and CE3, such that the light emitting layers EL1, EL2, and EL3 may emit light.

The common electrodes CE1, CE2, and CE3 may include a first common electrode CE1, a second common electrode CE2 and a third common electrode CE3, which are disposed in the different light emission areas EA1, EA2, and EA3, respectively. The first common electrode CE1 may be disposed on the first light emitting layer EL1 in the first light emission area EA1, the second common electrode CE2 may be disposed on the second light emitting layer EL2 in the second light emission area EA2, and the third common electrode CE3 may be disposed on the third light emitting layer EL3 in the third light emission area EA3. The first to third common electrodes CE1, CE2, and CE3 may be spaced apart from one another.

The common electrodes CE1, CE2, and CE3 may include a first element of silver (Ag) and a second element of group XV element. The common electrodes CE1, CE2, and CE3 may have a single-layer or multi-layer structure and may include a first layer including a first element of silver (Ag) and a second element of group XV element. In an embodiment, the second element may be one or two selected from bismuth (Bi) and antimony (Sb).

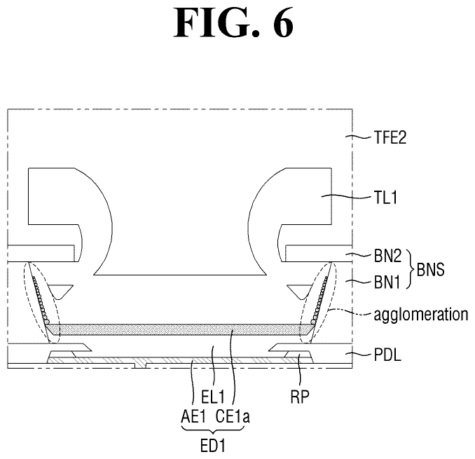

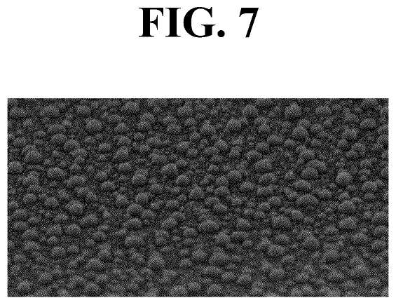

In a case where the common electrodes CE1, CE2, and CE3 do not include the second element of group XV element but only include silver (Ag), agglomeration occurs in a very thin film. FIGS. 6 and 7 are a cross-sectional view and a scanning electron microscope (SEM) image showing the agglomeration phenomenon of a common electrode CE1a containing only silver (Ag) (Comparative Example 1). Referring to FIG. 6, it is shown that a common electrode CE1a deposited on the side surface of a first bank BN1 is agglomerated. FIG. 7 shows an agglomeration phenomenon occurred in silver (Ag) electrode of 50 angstrom (Å) thickness observed using a scanning electron microscope (SEM). The agglomeration of the common electrodes CE1, CE2, and CE3 may increase contact resistance and cause deterioration of light emitting elements ED1, ED2, and ED3.

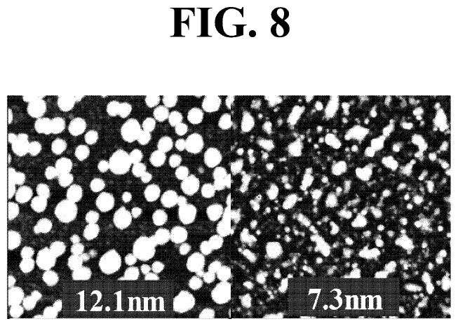

Agglomeration may also occur when the common electrodes CE1, CE2, and CE3 includes elements other than group XV element in addition to silver (Ag). FIG. 8 is an atomic force microscope (AFM) image showing the agglomeration phenomenon of common electrodes CE1, CE2, and CE3 (Comparative Example 2) containing Ag—In alloy or Ag—Pd—Cu alloy. FIG. 8 shows a surface of an alloy thin film after heat treatment of the alloy thin film of 150 Å thickness at 250° C. for one hour that is observed through the AFM. FIG. 8 shows that the surface roughness of about 12.1 nanometers (nm) is measured in Ag—In alloy, and the surface roughness of about 7.3 nm is measured in Ag—Pd—Cu alloy.

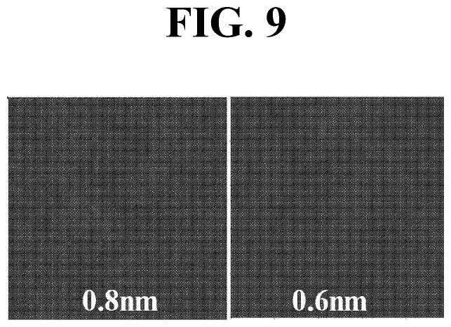

As in an embodiment, in a case where the common electrodes CE1, CE2, and CE3 include the first element of silver (Ag) and the second element of group XV element together, agglomeration phenomenon does not occur. FIG. 9 is an atomic force microscope (AFM) image showing the agglomeration phenomenon of common electrodes CE1, CE2, and CE3 (Example 1) including Ag—Bi alloy or Ag—Sb alloy. FIG. 9 shows a surface of an alloy thin film after heat treatment of the alloy thin film of 150 Å thickness at 250° C. for one hour that is observed through the AFM. FIG. 9 shows that the surface roughness of about 0.8 nm is measured in Ag—Bi alloy, and the surface roughness of about 0.6 nm is measured in Ag—Sb alloy. In the case where the common electrodes CE1, CE2, and CE3 includes both the first element of silver (Ag) and the second element of group XV element, it can be seen that the surface roughness is significantly reduced and agglomeration phenomenon does not occur.

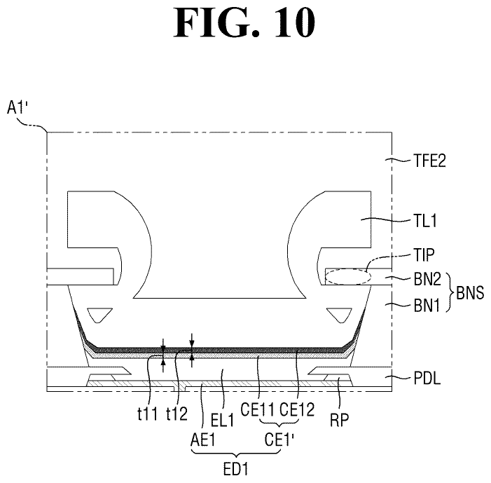

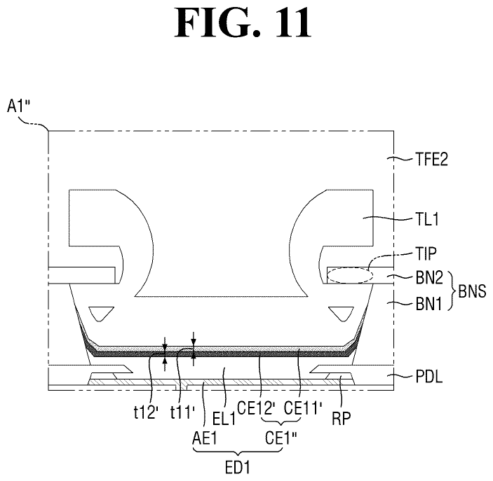

FIGS. 10 and 11 are cross-sectional views respectively showing a portion of a display device according to an embodiment, in which the common electrodes CE1, CE2, and CE3 have a multi-layer structure. The first common electrode CE1 in the embodiment of FIG. 5 has a single-layer structure of a first layer CE1 including a first element of silver (Ag) and a second element of group XV element, and the first common electrode CE1′ in the embodiment of FIG. 10 and the first common electrode CE1″ in the embodiment of FIG. 11 have a multi-layer structure that further includes other layers in addition to the first layer CE11 or CE11′.

In an embodiment, the ratio of the second element to the total number of atoms included in the first layer CE1, CE11, or CE11′ may be in a range of about 0.2 atomic percent (at %) to about 5.0 at %. In an embodiment, the ratio of the second element to the total number of atoms included in the first layer CE1, CE11, or CE11′ may be in a range of about 0.5 at % to about 3.0 at %. In such an embodiment where the ratio of the second element to the total number of atoms included in the first layer CE1, CE11, or CE11′ is the above range, the electrode can be formed uniformly and agglomeration of silver (Ag) can be effectively prevented. Elemental ratios or atomic ratios may be obtained by transmission electron microscopy (TEM) or energy-dispersive X-ray (EDX) composition analysis.

In an embodiment, the first layer CE1, CE11, or CE11′ may further include a third element in addition to the first and second elements. The third element may be at least one selected from copper (Cu), zinc (Zn), indium (In), and tin (Sn).

In an embodiment, the ratio of the third element to the total number of atoms included in the first layer CE1, CE11, or CE11′ may be in a range of about 0.2 at % to about 3.0 at %. In such an embodiment where the ratio of the third element to the total number of atoms included in the first layers CE1, CE11, and CE11′ is the above range, the electrode may have a thin thickness. In an embodiment, the sum of the ratio of the second and third elements to the total number of atoms included in the first layer CE1, CE11, or CE11′ may be in a range of about 0.5 at % to about 3.0 at %. The second and third elements included in the first layer CE1, CE11, or CE11′ may have a same ratio as each other or different atomic ratios, respectively. In an embodiment, for example, the ratio of the second element included in the first layer CE1, CE11, or CE11′ may be greater than the ratio of the third element included in the first layer CE1, CE11, or CE11′.

The ratio of the first element of silver (Ag) included in the first layer CE1, CE11, or CE11′ may be considerably greater than the second element and/or the third element therein. The ratio of the first element to the total number of atoms included in the first layer CE1, CE11, or CE11′ may be in a range of about 95.0 at % to about 99.8 at %, or in a range of about 97.0 at % to about 99.5% at %.

In some embodiments, the common electrode CE1′ or CE1″ may further include first layers CE11 or CE11′ and second layers CE12 or CE12′, respectively. The second layer CE12 or CE12′ may include one or two selected from pure silver (pure Ag) and an AgMg alloy.

Referring to FIG. 10, in an embodiment, the first layer CE11 may be disposed on the light emitting layer EL1, and the second layer CE12 may be disposed on the first layer CE11. Referring to FIG. 11, in an embodiment, the second layer CE12′ may be disposed on the light emitting layer EL1, and the first layer CE11′ may be disposed on the second layer CE12′.

The common electrode CE1, CE2, or CE3 may have a thin thickness. In an embodiment, the thickness t1, t11+t12, or t11′+t12′ of each of the common electrodes CE1, CE2, and CE3 may be in a range of about 90 Å to about 150 Å, or in a range of about 90 Å to about 120 Å. The common electrodes CE1, CE2, and CE3 are ultra-thin, but do not have agglomeration problems.

The thickness t11 or t11′ of the first layer CE11 or CE11′ and the thickness t12 or t12′ of the second layer CE12 or CE12′ may be the same as or similar to each other. In an embodiment, the thickness t11 or t11′ of the first layer CE11 or CE11′ may be 0.8 to 1.2 times each of the thickness t12 or t12′ of the second layer CE12 or CE12′, respectively.

The thickness of the common electrode CE1, CE2, or CE3, the first layer CE11 or CE11′, and the second layer CE12 or CE12′ is the thickness of the portion thereof overlapping the opening of the second bank BN2 in the corresponding layer, or the thickness of the thickest portion thereof.

The common electrode CE1, CE2, or CE3 may contact the first bank BN1. One end and an opposing end of the common electrodes CE1, CE2, and CE3 may contact the side surface of the first bank BN1 defining the opening. The spaced apart common electrodes CE1, CE2, and CE3 may be electrically connected to one another through the first bank BN1 and may receive a voltage.

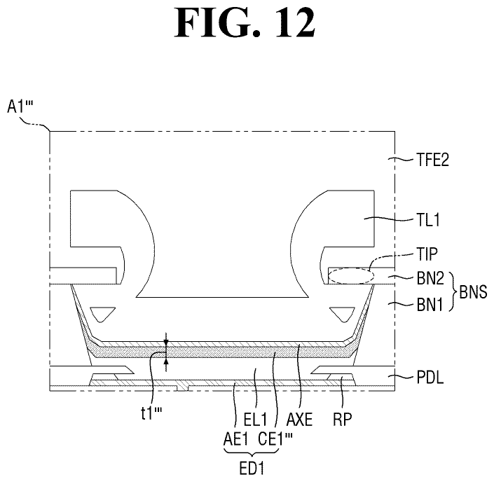

In an embodiment, an auxiliary electrode AXE may be disposed on the common electrodes CE1, CE2, and CE3. FIG. 12 illustrates a cross-section of an embodiment of a display device 10 including the auxiliary electrode AXE. The auxiliary electrode AXE may be disposed between the common electrodes CE1, CE2, and CE3 and a lower inorganic encapsulation layer TFE1 to assist electrical connection between the common electrodes CE1, CE2, and CE3. The auxiliary electrode AXE may be in contact with the common electrodes CE1, CE2, and CE3 and the first bank BN1.

The auxiliary electrode AXE may include a transparent conductive oxide (TCO). At least one selected from indium tin oxide (ITO), indium zinc oxide (IZO), indium tin zinc oxide (ITZO), zinc-indium-tin oxide (ZITO), indium-gallium-zinc oxide (IGZO), indium-tin oxide (IZO) and zinc-tin oxide (ZTO) may be used as the material of the transparent conductive oxide (TCO).

In an embodiment, a capping layer (not shown) may be disposed on the common electrodes CE1, CE2, and CE3. The capping layer may include an organic or inorganic insulating material and cover the patterns disposed on the light emitting elements ED1, ED2, and ED3. The capping layer may effectively prevent the light emitting elements ED1, ED2, and ED3 from being damaged by external air. In an embodiment, the capping layer may include an organic material such as a-NPD, NPB, TPD, m-MTDATA, Alq₃, LiF and/or CuPc or an inorganic material such as aluminum oxide, titanium oxide, tantalum oxide, hafnium oxide, zinc oxide, silicon oxide, silicon nitride and/or silicon oxynitride.

Referring back to FIG. 4, an embodiment of the display device 10 may include a plurality of bank structures BNS disposed on the pixel defining layer PDL. The bank structure BNS may have a structure in which banks BN1 and BN2 including different materials are sequentially stacked, may define a plurality of openings corresponding to the light emission areas EA1, EA2, and EA3, and may be disposed to overlap light blocking area of the color filter layer CFL, which will be described later. The light emitting elements ED1, ED2, and ED3 of the display device 10 may be disposed to overlap the opening of the bank structure BNS.

The first bank BN1 may be disposed on the pixel defining layer PDL. A side surface of the first bank BN1 may be more depressed than a corresponding side surface of the pixel defining layer PDL in a direction opposite to the direction toward the centers of the light emission areas EA1, EA2, and EA3. The side surface of the first bank BN1 may be more depressed than a corresponding side surface of a second bank BN2, which will be described later, in the direction opposite to the direction toward the light emission areas EA1, EA2, and EA3.

According to an embodiment, the first bank BN1 may include a metal material. In an embodiment, the first bank BN1 may include aluminum (Al), an oxide of aluminum (Al), or an alloy of aluminum (Al).

The light emitting layers EL1, EL2, and EL3 may be in direct contact with the side surface of the first bank BN1. A contact area between the common electrodes CE1, CE2, and CE3 and the side surface of the first bank BN1 may be greater than a contact area between the light emitting layers EL1, EL2, and EL3 and the side surface of the first bank BN1. The common electrodes CE1, CE2, and CE3 may be disposed to have a greater area than the light emitting layers EL1, EL2, and EL3 on the side surface of the first bank BN1, or at a higher position on the side surface of the first bank BN1. Since the common electrodes CE1, CE2, and CE3 of the different light emitting elements ED1, ED2, and ED3 are electrically connected to one another through the first bank BN1, areas of the common electrodes CE1, CE2, and CE3 to be in contact with the first bank BN1 may become substantially great.

The first bank BN1 may have an upper surface positioned higher than the common electrodes CE1, CE2, and CE3. A height from the substrate SUB to the upper surface of the first bank BN1 may be greater than a height from the substrate SUB to the common electrodes CE1, CE2, and CE3.

The second bank BN2 may be disposed on the first bank BN1. The second bank BN2 may define openings that overlap each of the light emission areas EA1, EA2, and EA3, and each opening may be defined a side surface thereof. The second bank BN2 may include a tip TIP or eaves, which is a protruding portion with respect to the first bank BN1 in a plan view or when viewed in the third direction DR3. The side surface of the second bank BN2 may protrude toward centers of the light emission areas EA1, EA2, and EA3 more than the corresponding side surface of the first bank BN1.

As the side surface of the second bank BN2 has a shape that protrudes toward the light emission areas EA1, EA2, and EA3 more than the corresponding side surface of the first bank BN1, an undercut structure of the first bank BN1 may be formed below the tip of the second bank BN2.

In the display device 10 according to an embodiment, as the bank structure BNS includes the tip TIP protruding toward centers of the light emission areas EA1, EA2, and EA3, the light emitting layers EL1, EL2, and EL3 and the common electrodes CE1, CE2, and CE3 that are spaced apart from each other may be formed through a deposition and etching process rather than a mask process. In addition, it is possible to individually form different layers in different light emission areas EA1, EA2, and EA3 through the deposition process. For example, even if the light emitting layers EL1, EL2, and EL3 of the light emitting elements ED1, ED2, and ED3 and the common electrodes CE1, CE2, and CE3 are formed through a deposition process without using a mask, the deposited materials may not be connected between the light emission areas EA1, EA2, and EA3 and may be disconnected with the bank structure BNS interposed therebetween by the tip of the second bank BN2. It is possible to individually form different layers in different light emission areas EA1, EA2, and EA3 through a process of forming a material for forming a specific layer on the entire surface of the display device 10 and then etching and removing a layer formed in an unwanted area. An undesired configuration additionally provided for the mask process may be omitted from the display device 10, and the area of the non-display area NDA may be minimized.

The second bank BN2 may include a metal material different from the metal material of the first bank BN1. The metal material of the second bank BN2 is removed by dry etching along with the metal material of the first bank BN1, and may be a material that has a substantially slower etching rate than that of the first bank BN1 or is not etched, when wet etched. In an embodiment, the first bank BN1 may include aluminum (Al), an oxide of aluminum (Al), or an alloy of aluminum (Al), and the second bank BN2 may include titanium (Ti), an oxide of titanium (Ti), or an alloy of titanium (Ti).

The tip of the second bank BN2 may overlap the common electrodes CE1, CE2, and CE3, the light emitting layers EL1, EL2, and EL3, and the pixel defining layer PDL in the direction DR3 perpendicular to the substrate SUB. The common electrodes CE1, CE2, and CE3 may be formed below the lower surface of the tip TIP of the second bank BN2. One end and an opposing end of the common electrodes CE1, CE2, and CE3 may overlap the second bank BN2 in the thickness direction DR3 of the substrate.

The thin film encapsulation layer TFEL may be disposed on the light emitting elements ED1, ED2, and ED3 and the bank structure BNS, and may cover the plurality of light emitting elements ED1, ED2, and ED3 and the bank structure BNS. The thin film encapsulation layer TFEL may include at least one inorganic film to prevent oxygen or moisture from being permeated into the light emitting element layer EML. The thin film encapsulation layer TFEL may include at least one organic film to protect the light emitting element layer EML from particles such as dust.

In an embodiment, the thin film encapsulation layer TFEL may include a lower inorganic encapsulation layer TFE1, an organic encapsulation layer TFE2 and an upper inorganic encapsulation layer TFE3, which are sequentially stacked.

Each of the lower inorganic encapsulation layer TFE1 and the upper inorganic encapsulation layer TFE3 may include one or more inorganic insulating materials. The inorganic insulating material may be at least one selected from silicon oxide, silicon nitride and silicon oxynitride, and may be, for example, aluminum oxide, titanium oxide, tantalum oxide, hafnium oxide, zinc oxide, silicon oxide, silicon nitride and silicon oxynitride.

The organic encapsulation layer TFE2 may include a polymer-based material. The polymer-based material may include an acrylic resin, an epoxy-based resin, polyimide and polyethylene. In an embodiment, the organic encapsulation layer TFE2 may include an acrylic resin, for example, polymethyl methacrylate, polyacrylic acid, etc. The organic encapsulation layer TFE2 may be formed by hardening a monomer or coating a polymer.

The lower inorganic encapsulation layer TFE1 may be disposed on the light emitting elements ED1, ED2, and ED3, and the bank structure BNS. The lower inorganic encapsulation layer TFE1 may include a first inorganic layer TL1, a second inorganic layer TL2, and a third inorganic layer TL3, which are disposed to correspond to the different light emission areas EA1, EA2, and EA3, respectively. Each of the first inorganic layer TL1, the second inorganic layer TL2 and the third inorganic layer TL3 may include an inorganic insulating material to cover the light emitting elements ED1, ED2, and ED3. The first inorganic layer TL1, the second inorganic layer TL2 and the third inorganic layer TL3 may effectively prevent the light emitting elements ED1, ED2, and ED3 from being damaged from the external air.

The lower inorganic encapsulation layers TFE1 (TL1, TL2, and TL3) may be formed through a chemical vapor deposition (CVD) method, and thus may be formed along a step difference of the deposited layers. In an embodiment, for example, the first inorganic layer TL1, the second inorganic layer TL2 and the third inorganic layer TL3 may form a thin film even under the undercut due to the tip TIP of the bank structure BNS. The lower inorganic encapsulation layers TL1, TL2, and TL3 may be disposed along the upper surface of the second bank BN2, the side surface of the first bank BN1, and the upper surface of the common electrodes CE1, CE2, and CE3. The lower inorganic encapsulation layers TL1, TL2, and TL3 may be in contact with the lower surface of the second bank BN2, thereby preventing moisture permeation from external air.

The first inorganic layer TL1 may not overlap the second light emitting element ED2 and the third light emitting element ED3, but may be disposed only on the first light emitting element ED1 and the bank structure BNS in the periphery thereof. The second inorganic layer TL2 may not overlap the first light emitting element ED1 and the third light emitting element ED3, but may be disposed only on the second light emitting element ED2 and the bank structure BNS in the periphery thereof. The third inorganic layer TL3 may not overlap the first light emitting element ED1 and the second light emitting element ED2, but may be disposed only on the third light emitting element ED3 and the bank structure BNS in the periphery thereof.

The first inorganic layer TL1 may be formed after the first common electrode CE1 is formed, the second inorganic layer TL2 may be formed after the second common electrode CE2 is formed, and the third inorganic layer TL3 may be formed after the third common electrode CE3 is formed. The first inorganic layer TL1, the second inorganic layer TL2 and the third inorganic layer TL3 may be spaced apart from one another on the bank structure BNS.

The lower inorganic encapsulation layers TL1, TL2, and TL3 may be disposed on the upper and lower surfaces of the light emitting elements ED1, ED2, and ED and the second bank BN2 in the periphery thereof, but may be separated from the upper surface of the second bank BN2. That is, the lower inorganic encapsulation layers TL1, TL2, and TL3 may have an undercut structure on the second bank BN2. The space between the lower inorganic encapsulation layers TL1, TL2, and TL3 and the upper surface of the second bank BN2 may be a space in which the materials of the light emitting layers EL1, EL2, and EL3, and the common electrodes CE1, CE2, and CE3 deposited on the front surface is removed.

The organic encapsulation layer TFE2 is disposed on the second bank BN2 and the lower inorganic encapsulation layers TL1, TL2, and TL3. A portion of the organic encapsulation layer TFE2 may be disposed in the space between the lower inorganic encapsulation layers TL1, TL2, and TL3 and the upper surface of the second bank BN2. In the area where the second bank BN2 and the lower inorganic encapsulation layers TL1, TL2, and TL3 overlap, the second bank BN2, the organic encapsulation layer TFE2, and the lower inorganic encapsulation layers TL1, TL2, and TL3 may be sequentially stacked. In the tip TIP area, the organic encapsulation layer TFE2 and the lower inorganic encapsulation layers TL1, TL2, and TL3 may be arranged sequentially on a top surface of the second bank BN2, and the organic encapsulation layer TFE2 may be disposed again on a top surface of the lower inorganic encapsulation layers TL1, TL2, and TL3. In other words, a portion of the organic encapsulation layer TFE2 may be disposed between the upper surface of the second bank BN2 and the lower inorganic encapsulation layers TL1, TL2, and TL3 on the tip TIP of the second bank BN2, and the other portion thereof may be disposed on top surfaces of the lower inorganic encapsulation layers TL1, TL2, and TL3.

In an embodiment, the entire upper surface of the second bank BN2 may be in contact with the organic encapsulation layer TFE2. The first lower surface of the lower inorganic encapsulation layers TL1, TL2, and TL3 may be a surface opposite to the upper surface of the second bank BN2, and the first lower surface of the lower inorganic encapsulation layers TL1, TL2, and TL3 may be in contact with the organic encapsulation layer TFE2. The organic encapsulation layer TFE2 may be in contact with the side surface of the second bank BN2.

The upper inorganic encapsulation layer TFE3 may be disposed on the organic encapsulation layer TFE2. The upper inorganic encapsulation layer TFE3 may include at least one selected from aluminum oxide, titanium oxide, tantalum oxide, hafnium oxide, zinc oxide, silicon oxide, silicon nitride and silicon oxynitride.

A light blocking layer (not shown) may be selectively disposed on the thin film encapsulation layer TFEL. The light blocking layer may be positioned among the light emission areas EA1, EA2, and EA3. The light blocking layer may include a light absorbing material. In an embodiment, for example, the light blocking layer may include an inorganic black pigment or an organic black pigment. The inorganic black pigment may be carbon black, and the organic black pigment may include at least one of lactam black, perylene black or aniline black, but is not limited thereto. The light blocking layer may effectively prevent color mixture from occurring due to permeation of visible light among the first to third light emission areas EA1, EA2, and EA3, thereby improving a color reproduction rate of the display device 10.

The display device 10 may include a plurality of color filters CF1, CF2, and CF3 disposed on the light emission areas EA1, EA2, and EA3. Each of the plurality of color filters CF1, CF2, and CF3 may include a filtering pattern area and a light blocking area. The filtering pattern area may be formed to overlap the light emission areas EA1, EA2, and EA3 or the opening of the bank structure BNS, and may form a light output area from which the light emitted from the light emission areas EA1, EA2, and EA3 is output. The light blocking area is an area in which the plurality of color filters CF1, CF2, and CF3 are stacked so that light cannot be transmitted therethrough.

The color filters CF1, CF2, and CF3 may include a first color filter CF1, a second color filter CF2, and a third color filter CF3, which are disposed to correspond to the different light emission areas EA1, EA2, and EA3, respectively. The color filters CF1, CF2, and CF3 may include a colorant such as a dye or pigment for absorbing light of another wavelength band other than light of a specific wavelength band, and may be disposed to correspond to colors of light emitted from the light emission areas EA1, EA2, and EA3. In an embodiment, for example, the first color filter CF1 may be a red color filter disposed to overlap the first light emission area EA1, for transmitting only first light of red color. The second color filter CF2 may be a green color filter disposed to overlap the second light emission area EA2, for transmitting only second light of green color. The third color filter CF3 may be a blue color filter disposed to overlap the third light emission area EA3, for transmitting only third light of blue color.

In an embodiment, the display device 10 may reduce the intensity of reflective light due to external light as the color filters CF1, CF2, and CF3 are disposed to overlap one another. In such an embodiment, a color sense of the reflective light due to external light may be controlled by adjustment of layout, shape, area or the like of the color filters CF1, CF2, and CF3 on a plan view.

An overcoat layer OC may be disposed on the color filters CF1, CF2, and CF3 to planarize upper ends of the color filters CF1, CF2, and CF3. The overcoat layer OC may be a colorless light-transmissive layer having no color of a visible light band. In an embodiment, for example, the overcoat layer OC may include a colorless light-transmissive organic material such as an acrylic resin.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a first pixel electrode disposed on a substrate;
a pixel defining layer disposed on the substrate and provided with an opening exposing the first pixel electrode;
a first light emitting layer disposed on the first pixel electrode;
a first common electrode disposed on the first light emitting layer and comprising a first layer;
a first bank disposed on the pixel defining layer; and
a second bank disposed on the first bank, wherein a side surface of the second bank is protruding more than a corresponding side surface of the first bank,
wherein the first layer comprises a first element of silver (Ag) and a second element of group XV element.

2. The display device of claim 1,
wherein a ratio of the second element to a total number of atoms in the first layer is in a range of about 0.2 at % to about 5.0 at %.

3. The display device of claim 1,
wherein the second element is one or two selected from bismuth (Bi) and antimony (Sb).

4. The display device of claim 1,
wherein the first layer further comprises a third element comprising at least one selected from copper (Cu), zinc (Zn), indium (In), and tin (Sn).

5. The display device of claim 4,
wherein a sum of ratios of the second and third elements to a total number of atoms in the first layer is about 0.5 at % or greater.

6. The display device of claim 5,
wherein a ratio of the second element to the total number of atoms in the first layer is greater than a ratio of the third element to the total number of atoms in the first layer.

7. The display device of claim 1,
wherein the first common electrode further comprises a second layer comprising at least one selected from pure silver (pure Ag) and an AgMg alloy.

8. The display device of claim 7,
wherein the first layer is disposed on the first light emitting layer, and
the second layer is disposed on the first layer.

9. The display device of claim 7,
wherein the second layer is disposed on the first light emitting layer, and
the first layer is disposed on the second layer.

10. The display device of claim 1,
wherein a thickness of the first common electrode is in a range of about 90 Å to about 150 Å.

11. The display device of claim 7,
wherein a thickness of the first layer is 0.8 to 1.2 times a thickness of the second layer.

12. The display device of claim 1, further comprising an auxiliary electrode disposed on the common electrode.

13. The display device of claim 12,
wherein the auxiliary electrode comprises a transparent conductive oxide (TCO).

14. The display device of claim 1, further comprising a residual pattern disposed between an upper surface of the first pixel electrode and a lower surface of the pixel defining layer.

15. A display device comprising:
a first pixel electrode disposed on a substrate;
a pixel defining layer disposed on the substrate and provided with an opening exposing the first pixel electrode;
a first light emitting layer disposed on the first pixel electrode;
a first common electrode disposed on the first light emitting layer and comprising a first element of silver (Ag) and a second element of group XV element;
a first bank disposed on the pixel defining layer;
a second bank disposed on the first bank, wherein a side surface of the second bank is protruding more than a corresponding side surface of the first bank;
a first inorganic layer disposed on the first common electrode and the second bank; and
an organic encapsulation layer disposed between the second bank and the first inorganic layer.

16. The display device of claim 15,
wherein the first common electrode comprises:
a first layer comprising the first element of silver (Ag) and the second element of group XV element; and
a second layer comprising at least one selected from pure silver (pure Ag) and an AgMg alloy.

17. The display device of claim 15,
wherein the first inorganic layer is in contact with a lower surface of the second bank.

18. The display device of claim 15,
wherein the organic encapsulation layer is in contact with the side surface of the second bank.

19. A display device comprising:
a first pixel electrode disposed on a substrate;
a pixel defining layer disposed on the substrate and provided with an opening exposing the first pixel electrode;
a first light emitting layer disposed on the first pixel electrode;
a first common electrode disposed on the first light emitting layer and comprising a first layer;
a first bank disposed on the pixel defining layer; and
a second bank disposed on the first bank, wherein a side surface of the second bank is protruding more than a corresponding side surface of the first bank,
wherein the first layer comprises a first element of silver (Ag), one or two second elements selected from bismuth (Bi) and antimony (Sb), and a third element comprising at least one selected from copper (Cu), zinc (Zn), indium (In), and tin (Sn), and
a ratio of the first element to a total number of atoms in the first layer is about 95.0 at % or greater.

20. The display device of claim 19,
wherein a thickness of the first common electrode is in a range of about 90 Å to about 150 Å.
